(19) United States
(12) Patent Application Publication
(10) Pub. No.: US 2025/0379067 A1
(43) Pub. Date: Dec. 11, 2025

(54) SEALING STRUCTURES FOR PROCESSING CHAMBERS

(71) Applicant: Applied Materials, Inc., Santa Clara, CA (US)

(72) Inventors: Benjamin Gross, Castro Valley, CA (US); Hari K. Ponnekanti, San Jose, CA (US); David Soltz, Redwood City, CA (US)

(21) Appl. No.: 19/051,154

(22) Filed: Feb. 11, 2025

Related U.S. Application Data
(60) Provisional application No. 63/656,691, filed on Jun. 6, 2024.

(51) Int. Cl. H01L 21/67

(52) U.S. Cl. CPC H01L 21/67017

(57) ABSTRACT

Sealing structures for processing chambers are provided. For example, a system can include a base sealing structure, and an elastomer bonded to a surface of the base sealing structure to form a sealing structure. As another example, a system can include a lid of a processing chamber, a body of processing chamber, an elastomer sealing structure located between the lid and the body, wherein the elastomer sealing structure has a ribbon shape and includes a material that lacks per- and/or polyfluoroalkyl substances (PFAS).

### CROSS-REFERENCE TO RELATED APPLICATION(S)

The present application claims priority to U.S. Provisional Patent Application No. 63/656,691, filed on Jun. 6, 2024 and entitled “ELASTOMER COATED SEALING STRUCTURES FOR PROCESSING CHAMBERS”, the entire contents of which are hereby incorporated by reference herein.

### TECHNICAL FIELD

Embodiments of the present disclosure relate to electronic device fabrication generally. Particularly, embodiments of the present disclosure relate to sealing structures for processing chambers.

### BACKGROUND

Semiconductor manufacturing processes involve intricate steps that demand precise control over environmental conditions, such as pressure, temperature, gas composition, etc. Vacuum chambers can be used to create and maintain the environment for these processes. They can include sealed enclosures used to provide controlled, low-pressure environments (e.g., significantly lower than atmospheric pressure) that are conducive to the deposition of films, etching of substrates, and other operations used to fabricate semiconductor devices. Vacuum chambers can incorporate pumping systems to evacuate air and create a vacuum within the enclosure. Additionally, various components such as gas inlets, substrate holders, and monitoring sensors are integrated into the chamber to facilitate semiconductor processing operations.

### SUMMARY

According to embodiments described herein is a system. The system includes a base sealing structure, and an elastomer bonded to a surface of the base sealing structure to form a sealing structure.

According to embodiments described herein is a system. The system includes a lid of a processing chamber, a body of processing chamber, and an elastomer sealing structure located between the lid and the body. The elastomer sealing structure a ribbon shape and includes a material that lacks per- and/or polyfluoroalkyl substances (PFAS).

According to embodiments described herein is a method. The method includes causing, within a processing chamber including a lid and a body, at least one process to be performed using a corrosive chemistry. The elastomer sealing structure is located between the lid and the body. The elastomer sealing structure has a ribbon shape and includes a material that lacks per- and/or polyfluoroalkyl substances (PFAS). The method further includes determining whether to replace the elastomer sealing structure, and in response to determining to replace the elastomer sealing structure, causing the elastomer sealing structure to be replaced with a new elastomer sealing structure having a ribbon shape and comprising a material that lacks PFAS.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 a top schematic view of an example manufacturing system, in accordance with some embodiments.

FIG. 2A is a diagram illustrating a cross-sectional view of an example system including an elastomer coated sealing structure for a processing chamber, in accordance with some embodiments.

FIG. 2B is a diagram of example elastomer coated sealing structures, in accordance with some embodiments.

FIG. 3 is a diagram of example elastomer coated sealing structures, in accordance with some embodiments.

FIGS. 4A-4B are diagrams of example elastomer coated sealing structures, in accordance with some embodiments.

FIG. 5 is a flowchart of an example method to fabricate elastomer coated sealing structures for processing chambers, in accordance with some embodiments.

FIGS. 6A-6B are diagrams illustrating cross-sectional views of an example system including an elastomer sealing structure for a processing chamber, in accordance with some embodiments.

FIGS. 7A-7B are diagrams illustrating cross-sectional views of an example system including an elastomer sealing structure and a metal sealing structure for a processing chamber, in accordance with some embodiments.

FIGS. 8A-8B are diagrams illustrating views of an example elastomer sealing structure, in accordance with some embodiments.

FIG. 9 is a flowchart of an example method to implement an elastomer sealing structure for a processing chamber, in accordance with some embodiments.

### DETAILED DESCRIPTION

Embodiments described herein relate to sealing structures for processing chambers. Some processing chambers used for electronic device manufacturing (e.g., semiconductor device manufacturing) are vacuum sealed using sealing structures (e.g., O-rings, gaskets, T-rings, square O-rings, X-rings, D-rings, V-rings, rectangular rings, U-cups, S-shaped rings, or any other suitable sealing structures) formed entirely from elastomers. Elastomers are a type of polymer that exhibit elastic behavior. More particularly, an elastomer can stretch or deform when a force is applied to the elastomer, and the elastomer can return to its original shape when the force is removed. Elastomers can have a high degree of flexibility and resistance to impact and/or abrasion. Examples of elastomers include natural rubber, synthetic rubber, silicone, and polyurethane. The properties of elastomers can be modified by changing their material composition and/or manufacturing processes to achieve specific performance characteristics, such as increased durability, temperature resistance, or chemical resistance.

More specifically, sealing structures used to provide vacuum seals for processing chambers can be formed entirely from chemical-resistant elastomers that can resist degradation by process chemistries used in processing chambers. For example, some sealing structures used to provide vacuum seals for processing chambers can be formed from elastomers that include per- and/or polyfluoroalkyl substance (PFAS) materials. PFAS materials are a group of synthetic organic materials (e.g., compounds) characterized by strong carbon-fluorine bonds. PFAS materials can exhibit unique properties such as resistance to high temperatures, moisture, degradation, etc. PFAS materials are highly resistant to degradation, and are colloquially referred to as “forever chemicals.”

One concern with the use of PFAS materials is their persistence in the environment and their potential adverse health effects, since they can accumulate in the environment, water sources, and living organisms. Regulatory restrictions on the use of PFAS materials can make it more difficult and/or expensive to access PFAS materials to create vacuum seals for processing chambers.

To address these and other drawbacks, embodiments described herein provide for sealing structures for processing chambers.

In some embodiments, a sealing structure described herein includes an elastomer formed on (e.g., bonded to) a surface of a base sealing structure. The sealing structure can be a compressible or semi-compressible apparatus or device that can be used to seal a connection and/or a cover to a vacuum chamber. For example, a sealing structure described herein can be placed within a flange between two vacuum components to create a leak-proof seal when connecting two vacuum components via the flange.

In some embodiments, the base sealing structure is a metal base sealing structure formed from a metal. In some embodiments, the base sealing structure is a plastic base sealing structure formed from a plastic. In some embodiments, the elastomer includes a single layer of elastomer material. In some embodiments, the elastomer includes multiple layers of elastomer materials. Examples of base sealing structures include O-rings, gaskets, T-rings, square rings, X-rings, D-rings, V-rings, rectangular rings, U-cups, S-shaped rings, or any other suitable sealing structures.

In some embodiments, the surface of the base sealing structure includes a first portion to be exposed to a process chemistry and a second portion that will not be exposed to the process chemistry. In some embodiments, the elastomer includes a material resistant to the process chemistry that is formed on (e.g., bonded to) the first portion, and the second portion is not covered by the elastomer. For example, the material resistant to the process chemistry can include at least one PFAS material (e.g., at least one of: a perfluoroalkyl substance or a polyfluoroalkyl substance). Although the elastomer may be formed from a PFAS material, less PFAS material will be used to form the sealing structure as compared to a sealing structure that is formed entirely from a PFAS material. Accordingly, these embodiments can be used to reduce the amount of PFAS materials used to form sealing structures as compared to sealing structures formed entirely from PFAS materials. In other embodiments, the first portion is not covered by an elastomer, and the elastomer is formed on (e.g., bonded to) the second portion.

In some embodiments, the base sealing structure includes an O-ring (e.g., metal O-ring or plastic O-ring). For example, a cross-section of the base sealing structure can have a circular shape. Examples of base sealing structures with cross-sections having circular shapes include tori, toroids, etc. In some embodiments, the elastomer is formed around an entirety of the surface of the O-ring. For example, the elastomer can be formed from a material resistant to the process chemistry (e.g., at least one PFAS material).

In some embodiments, the elastomer is formed around less than entirety of the surface of the O-ring. For example, the elastomer can be formed on (e.g., bonded to) a first portion of the surface of the O-ring that is exposed to a region external to the processing chamber (e.g., atmosphere), and a second portion of the O-ring not covered by the elastomer is exposed to an opening to a processing chamber. In these embodiments, the second portion of the O-ring can be formed to be resistant to one or more processes chemistries that can be used by the processing chamber. For example, at least the second portion of the O-ring can be coated with a material resistant to the one or more process chemistries. In these embodiments, since the elastomer formed on the first portion of the O-ring is not exposed to the one or more process chemistries, the elastomer can be formed from any suitable elastomer material (e.g., non-PFAS or PFAS). Accordingly, these embodiments can be used to reduce or eliminate the amount of PFAS materials used to form sealing structures as compared to sealing structures formed entirely from PFAS materials.

As another example, the elastomer can be formed on (e.g., bonded to) a first portion of the surface of the O-ring that is exposed to an opening to a processing chamber, and a second portion of the surface of the O-ring is exposed to a region external to the processing chamber (e.g., atmosphere). In these embodiments, since the second portion of the closed loop is not exposed to the opening of the processing chamber, the second portion of the closed loop may be left untreated. In these embodiments, the elastomer can be formed from an elastomer material that is resistant to one or more processes chemistries that can be used by the processing chamber. For example, the elastomer can be formed from a suitable PFAS material. Accordingly, these embodiments can be used to reduce the amount of PFAS materials used to form sealing structures as compared to sealing structures formed entirely from PFAS materials.

In some embodiments, a cross-section of the base sealing structure has a non-circular shape. For example, the non-circular shape can be an open loop shape (e.g., a C-shaped loop). In these embodiments, an elastomer can formed on (e.g., bonded to) to an outer surface of the open loop, such that an inner surface of the open loop is left uncovered. In some embodiments, the open loop shape includes flared ends (e.g., a flange) that extend past the elastomer boundary. This can enable the use of less chemically resistant elastomers (e.g., silicone or other non-PFAS materials), and can extend the life of the seal as well.

In some embodiments, the elastomer formed on the outer surface of the open loop shape is exposed to a region external to a processing chamber (e.g., atmosphere), and the inner surface of the open loop is exposed to an opening of the processing chamber. In these embodiments, the inner surface of the open loop can be formed to be resistant to one or more processes chemistries that can be used by the processing chamber. For example, at least the inner surface of the open loop can be coated with a material resistant to the one or more process chemistries. In these embodiments, since the elastomer is not exposed to the opening of the processing chamber, the elastomer can be formed from any suitable elastomer material (e.g., non-PFAS or PFAS). Accordingly, these embodiments can be used to reduce or eliminate the amount of PFAS materials used to form sealing structures as compared to sealing structures formed entirely from PFAS materials.

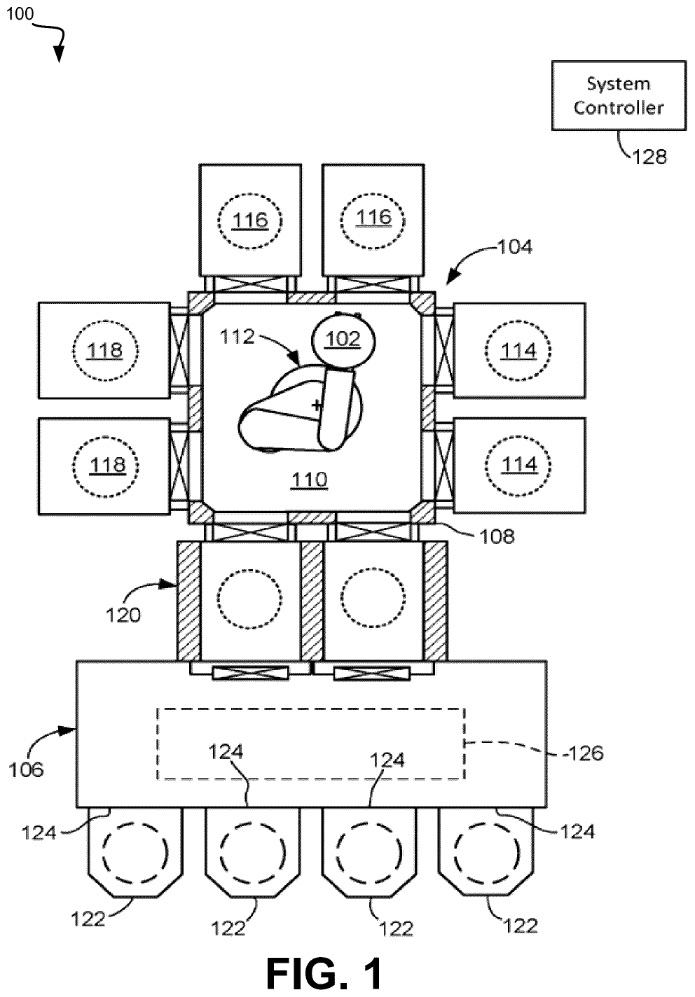

In some embodiments, the elastomer formed on the outer surface of the open loop is exposed to an opening of a processing chamber (e.g., and is exposed to process gases), and the inner surface of the open loop is exposed to a region external to the processing chamber (e.g., atmosphere). In these embodiments, the elastomer is formed from an elastomer material that is resistant to one or more processes chemistries that can be used by the processing chamber. For example, the elastomer can be formed from a suitable PFAS material. In these embodiments, since the inner surface of the open loop is not exposed to the opening of the processing chamber, the inner surface of the open loop may be left untreated. Accordingly, these embodiments can be used to reduce the amount of PFAS materials used to form sealing structures as compared to sealing structures formed entirely from PFAS materials. Further details regarding sealing structures including elastomers formed on base sealing structures will be described below with reference to FIGS. 1-5.

In some embodiments, a sealing structure described herein includes an elastomer sealing structure located between a lid of a processing chamber and a body of a processing chamber to maintain a vacuum seal. The sealing structure can provide a barrier against air from the atmosphere entering the processing chamber.

The elastomer sealing structure can be formed from a material (e.g., a polymer) that lacks PFAS (e.g., a non-PFAS material), and that can naturally break down upon disposal. One example of a material that can be used to form the elastomer sealing structure is polyethylene ((C₂H₄)ₙ). In some embodiments, the elastomer sealing structure is formed from high-density polyethylene (HDPE). For example, the elastomer sealing structure can be formed from polyethylene having a density of greater than or equal to about 900 kilograms per cubic meter (kg/m³). In some embodiments, the elastomer sealing structure is formed from crosslinked polyethylene (XLPE) or high-density crosslinked polyethylene (XLHDPE). Other examples of materials (e.g., polymers) include polypropylene, polyimide, nylon (e.g., nylon 66), ethylene-propylene diene monomer (EPDM), silicone rubber, etc. However, any suitable polymer that can naturally break down after disposal including at least one of: carbon (C), hydrogen (H), oxygen (O), nitrogen (N), silicon (Si), sulfur(S), etc. can be used to form the elastomer sealing structure in accordance with embodiments described herein.

The elastomer sealing structure can be a sacrificial sealing structure to be exposed to a corrosive chemical environment within the processing chamber. If the elastomer sealing structure is formed from a non-PFAS material, then the corrosive chemical environment can cause erosion of the elastomer sealing structure over time. The elastomer sealing structure can have a shape that, as the elastomer sealing structure is eroded by the corrosive chemical environment, can cause the compressive force exerted by the lid and the body onto elastomer sealing structure to shift toward the center of the remaining portion of the elastomer sealing structure to maintain the seal. For example, the elastomer sealing structure can have a ribbon shape (e.g., a wide ribbon shape), instead of a traditional O-ring shape. For example, the ribbon shape can be a flattened O-ring shape, similar to a rubber band.

The elastomer sealing structure can have a suitable width so that it does not substantially interfere with other components in the wall of the processing chamber. In some embodiments, the elastomer sealing structure has a width that is less than or equal to about 1 centimeter (cm). In some embodiments, the elastomer sealing structure has a width to height aspect ratio (“aspect ratio”) of less than or equal to about 100:1. In some embodiments, the elastomer sealing structure has an aspect ratio of less than or equal to about 50:1. In some embodiments, the elastomer sealing structure has an aspect ratio of less than or equal to about 10:1. In some embodiments, the elastomer sealing structure has an aspect ratio of less than or equal to about 5:1. In some embodiments, the elastomer sealing structure has an aspect ratio of less than or equal to about 1:1.

In some embodiments, a metal sealing structure is located between the lid and the body of the processing chamber to form a barrier against air from the atmosphere (e.g., a vacuum seal). For example, the metal sealing structure can be a metal O-ring, a metal gasket, etc. The metal sealing structure can provide a barrier against air from the atmosphere entering the process chamber. The metal sealing structure can be formed from a metal that can be eroded by the corrosive chemical environment within the processing chamber. Thus, in these “hybrid sealing structure” embodiments, the elastomer sealing structure is configured to function as a sacrificial sealing structure to protect the metal sealing structure from the corrosive chemical environment within the processing chamber. Accordingly, in these embodiments, the metal sealing structure is primarily responsible for forming the vacuum seal, and the elastomer sealing structure primarily functions as a barrier for the metal sealing structure against the corrosive chemical environment. In some embodiments, the metal sealing structure is bonded to the elastomer sealing structure.

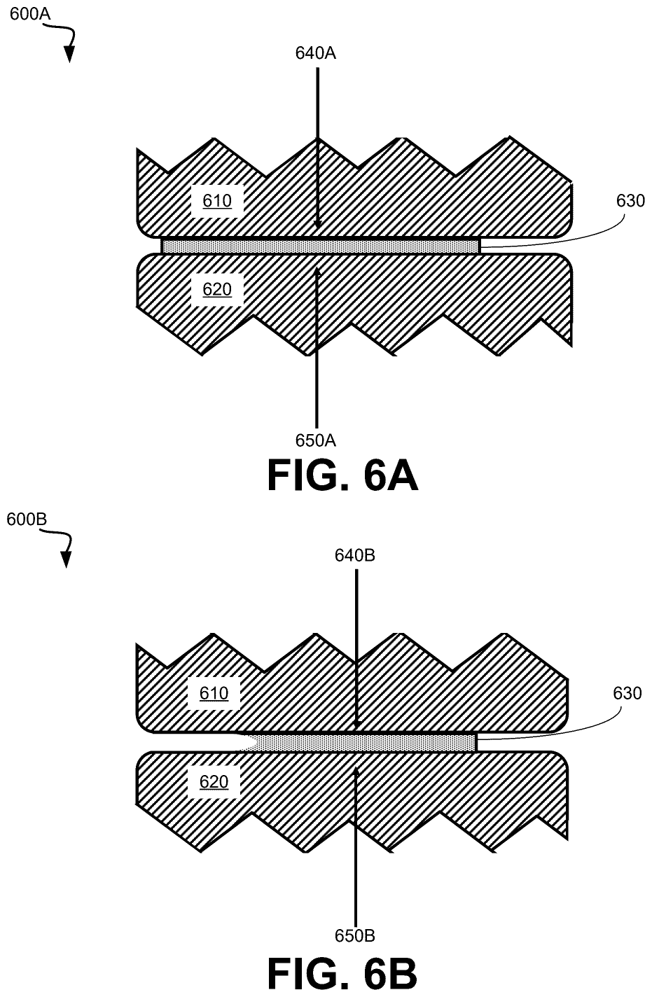

Since the elastomer sealing structure is formed from a non-PFAS material that erodes upon exposure to a corrosive chemical environment, the elastomer sealing structure will eventually need to be replaced when the remaining portion of the elastomer sealing structure satisfies a threshold condition (e.g., when the cross-sectional length of the elastomer sealing structure is less than or equal to a threshold length). Based on an analysis of corrosion rate of the elastomer sealing structure over time, a preventative maintenance schedule (e.g., based on maintenance cycles) can be devised to determine (e.g., predict) when to replace the elastomer sealing structure. For example, the elastomer sealing structure can be replaced if it determined that less than or equal to about 50% of the elastomer sealing structure is remaining. The frequency of this maintenance can be determined experimentally, can and depend on the process and/or application for which the elastomer sealing structure is being utilized. Further regarding elastomer sealing structures will be described below with reference to FIGS. 6A-9.

Embodiments described herein can provide a number of technical benefits. For example, embodiments described herein can reduce or eliminate hazardous material (e.g., PFAS material) usage, provide an improved vacuum seal as compared to metal-only or elastomer-only sealing structures, etc.

FIG. 1 is a top schematic view of an example manufacturing system, according to some embodiments. Manufacturing system 100 may perform one or more processes on a substrate 102. Substrate 102 may be any suitably rigid, fixed-dimension, planar article, such as, e.g., a silicon-containing disc or wafer, a patterned wafer, a glass plate, or the like, suitable for fabricating electronic devices or circuit components thereon. In some embodiments, substrate 102 can be a production substrate (e.g., a substrate used for production of a product, such as an electronic device), a conditioning substrate (e.g., a substrate used during performance of one or more conditioning operations, such as an initialization process and/or a maintenance process), and/or any other type of substrate.

Manufacturing system 100 may include a process tool 104 and a factory interface 106 coupled to process tool 104. Process tool 104 may include a housing 108 having a transfer chamber 110 therein. Transfer chamber 110 may include one or more processing chambers (also referred to as processing chambers) 114, 116, 118 disposed therearound and coupled thereto. Processing chambers 114, 116, 118 may be coupled to transfer chamber 110 through respective ports, such as slit valves or the like. Transfer chamber 110 may also include a transfer chamber robot 112 configured to transfer substrate 102 between processing chambers 114, 116, 118, load lock 120, etc. Transfer chamber robot 112 may include one or multiple arms where each arm includes one or more end effectors at the end of each arm. The end effector may be configured to handle particular objects, such as wafers.

Processing chambers 114, 116, 118 may be adapted to carry out any number of processes on substrates 102. A same or different substrate process may take place in each processing chamber 114, 116, 118. In some embodiments, processing chamber 114, 116, 118 can perform a substrate process for one or more substrates 102. A substrate process may include atomic layer deposition (ALD), physical vapor deposition (PVD), chemical vapor deposition (CVD), etching, annealing, curing, pre-cleaning, metal or metal oxide removal, or the like. In some embodiments, a substrate process may include a combination of two or more of atomic layer deposition (ALD), physical vapor deposition (PVD), chemical vapor deposition (CVD), etching, annealing, curing, pre-cleaning, metal or metal oxide removal, or the like. Other processes may be carried out on substrates therein. For example, an initialization process can be performed at one or more of processing chambers 114, 116, 118 to prepare processing chambers 114, 116, 118 for a substrate process. In another example, a maintenance process (e.g., a PM process, a CM process, etc.) can be performed to mitigate and/or correct wear or damage to components and/or an interior of processing chambers 114, 116, 118. Processing chambers 114, 116, 118 may each include one or more sensors configured to capture data for substrate 102 and/or an environment within processing chamber 114, 116, 118, before, after, or during a substrate process. In some embodiments, the one or more sensors may be configured to capture spectral data and/or non-spectral data for a portion of substrate 102.

A load lock 120 may also be coupled to housing 108 and transfer chamber 110. Load lock 120 may be configured to interface with, and be coupled to, transfer chamber 110 on one side and factory interface 106. Load lock 120 may have an environmentally controlled atmosphere that may be changed from a vacuum environment (wherein substrates may be transferred to and from transfer chamber 110) to an inert-gas environment at or near atmospheric-pressure (wherein substrates may be transferred to and from factory interface 106) in some embodiments.

Factory interface 106 may be any suitable enclosure, such as, e.g., an Equipment Front End Module (EFEM). Factory interface 106 may be configured to receive substrates 102 from substrate carriers 122 (e.g., Front Opening Unified Pods (FOUPs)) docked at various load ports of factory interface 106. A factory interface robot 126 (shown dotted) may be configured to transfer substrates 102 between substrate carriers (also referred to as containers) 122 and load lock 120. In other and/or similar embodiments, factory interface 106 may be configured to receive replacement parts from replacement parts storage containers 122.

Manufacturing system 100 may also be connected to a client device (not shown) that is configured to provide information regarding manufacturing system 100 to a user (e.g., an operator). In some embodiments, the client device may provide information to a user of manufacturing system 100 via one or more graphical user interfaces (GUIs). For example, the client device may provide information regarding one or more modifications to be made to a process recipe for a substrate 102 via a GUI.

Manufacturing system 100 may also include a system controller 128. System controller 128 may be and/or include a computing device such as a personal computer, a server computer, a programmable logic controller (PLC), a microcontroller, and so on. System controller 128 may include one or more processing devices, which may be general-purpose processing devices such as a microprocessor, central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device may also be one or more special-purpose processing devices such as an application specific integrated circuit (ASIC), a field programmable gate array (FPGA), a digital signal processor (DSP), network processor, or the like. System controller 128 may include a data storage device (e.g., one or more disk drives and/or solid state drives), a main memory, a static memory, a network interface, and/or other components. System controller 128 may execute instructions to perform any one or more of the methodologies and/or embodiments described herein. In some embodiments, system controller 128 may execute instructions to perform one or more operations at manufacturing system 100 in accordance with a process recipe. The instructions may be stored on a computer readable storage medium, which may include the main memory, static memory, secondary storage and/or processing device (during execution of the instructions).

System controller 128 may receive data from sensors included on or within various portions of manufacturing system 100 (e.g., processing chambers 114, 116, 118, transfer chamber 110, load lock 120, etc.). Data received by the system controller 128 may include spectral data and/or non-spectral data for a portion of substrate 102. For purposes of the present description, system controller 128 is described as receiving data from sensors included within processing chambers 114, 116, 118. However, system controller 128 may receive data from any portion of manufacturing system 100 and may use data received from the portion in accordance with embodiments described herein. In an illustrative example, system controller 128 may receive spectral data from one or more sensors for processing chamber 114, 116, 118 before, after, or during a substrate process at the processing chamber 114, 116, 118.

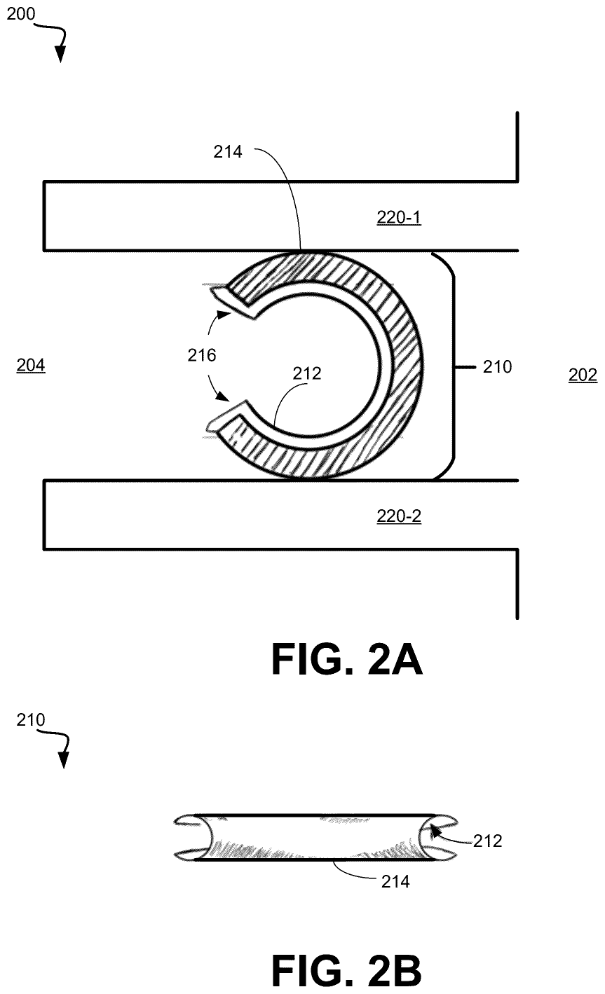

FIG. 2A is a block diagram of an example portion of a system 200 including a vacuum chamber, in accordance with some embodiments. As shown, the system 200 can include a processing chamber 202 and a region external to the processing chamber (e.g., atmosphere) 204. A sealing structure 210 can be placed between flanges 220-1 and 220-2 to form a seal between the processing chamber 202 and the region 204. The sealing structure 210 is shown in FIG. 2A as a cross-sectional view for clarity.

As shown, the sealing structure 210 can include a base sealing structure 212 and an elastomer 214 bonded to the base sealing structure 212. In some embodiments, the base sealing structure 212 is a metal base sealing structure formed from a metal. In some embodiments, the base sealing structure 212 is a plastic base sealing structure formed from a plastic. In some embodiments, the base sealing structure 212 is a C-shaped loop. For example, as further shown, the sealing structure 210 (e.g., the base sealing structure 212) can further include flared ends 216 located at respective ends of the sealing structure 210 that extend past the boundary of the elastomer 214. FIG. 2B is a perspective view of the sealing structure 210 including the base sealing structure 212 and the elastomer 214 formed on (e.g., bonded to) the base sealing structure 212.

In this illustrative example, the sealing structure 210 is placed between the flanges 220-1 and 220-2 such that the elastomer 214 formed on an outer surface of the base sealing structure 212 faces the region 202, and an inner surface of the base sealing structure 212 faces the processing chamber 204. The elastomer 214 can then be subject to exposure to one or more process chemistries used by the processing chamber 202. The elastomer 214 protects the base sealing structure 212, while the base sealing structure 212 can be primarily responsible for forming a vacuum seal. In some embodiments, the elastomer 214 is configured to be resistant to the one or more process chemistries. For example, the elastomer 214 can be formed from a material resistant to the one or more process chemistries, such as at least one suitable PFAS material. Although the elastomer 214 may be formed from a PFAS material, less PFAS material will be needed to form the sealing structure 210 as compared to a sealing structure that is formed entirely from a PFAS material. Accordingly, these embodiments can be used to reduce the amount of PFAS materials used to form sealing structures as compared to sealing structures formed entirely from PFAS materials.

In some embodiments, the elastomer 214 is not configured to be resistant to the one or more process chemistries. For example, the elastomer 214 can be formed from a non-PFAS material. In these embodiments, the elastomer 214 can degrade over time. Therefore, the sealing structure 210 may be periodically replaced over time.

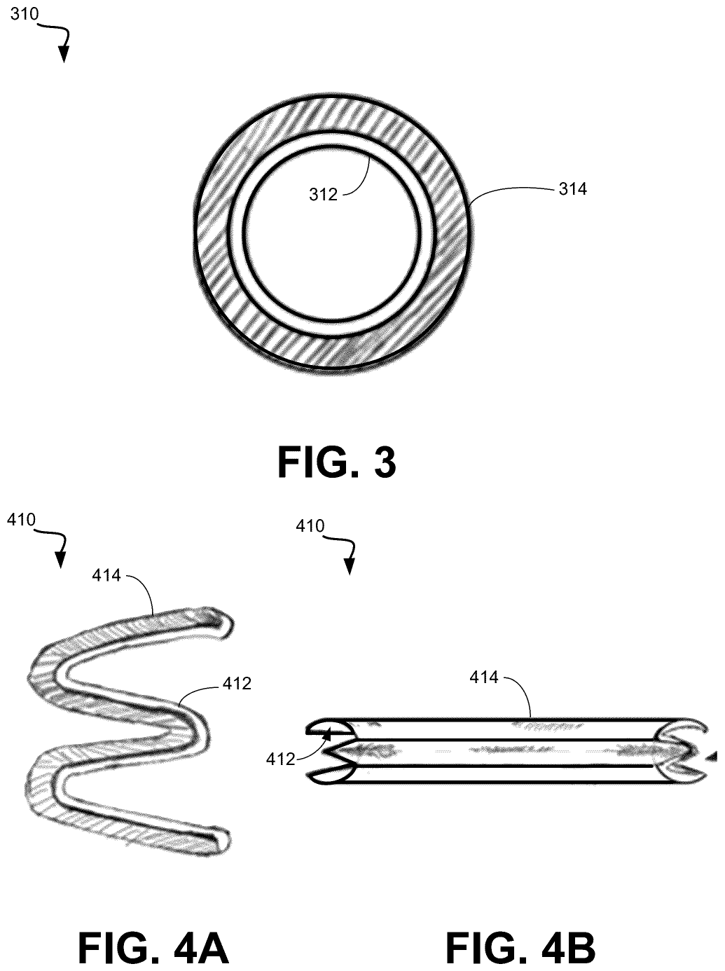

FIG. 3 is a cross-sectional view of an example sealing structure 310, in accordance with some embodiments. As shown, the sealing structure 310 includes a base sealing structure 312 and an elastomer 314 formed on (e.g., bonded to) the base sealing structure 312. In some embodiments, the base sealing structure 312 is a metal base sealing structure formed from a metal. In some embodiments, the base sealing structure 312 is a plastic base sealing structure formed from a plastic. In this illustrative example, the base sealing structure 312 has a cross-section having a circular shape (e.g., circular O-ring).

FIG. 4A is a cross-sectional view of an example sealing structure 410, in accordance with some embodiments. As shown, the sealing structure 410 includes a base sealing structure 412 and an elastomer 414 formed on (e.g., bonded to) the base sealing structure 412. In some embodiments, the base sealing structure 412 is a metal base sealing structure formed from a metal. In some embodiments, the base sealing structure 412 is a plastic base sealing structure formed from a plastic. In this illustrative example, the base sealing structure 412 has an S-shaped cross-section (e.g., an S-shaped loop or S-ring). FIG. 4B is a perspective view of the sealing structure 410 including the base sealing structure 412 and the elastomer 414 formed on (e.g., bonded to) the base sealing structure 412.

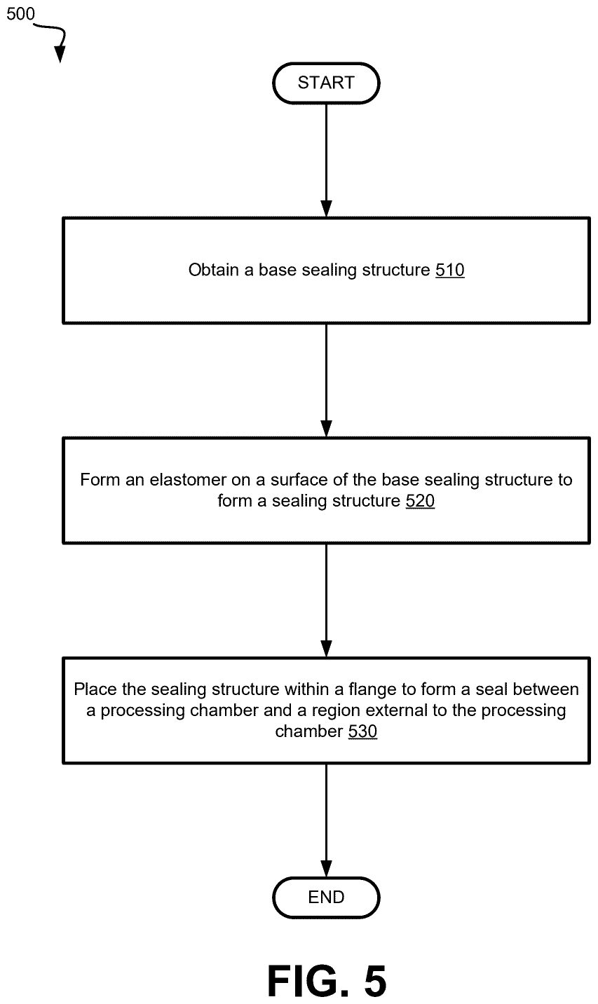

FIG. 5 is a flowchart of an example method 500 to implement elastomer coated sealing structures for processing chambers, in accordance with some embodiments. For example, an elastomer coated sealing structure may be similar to the sealing structure 210 of FIGS. 2A-2B, the sealing structure 310 of FIG. 3 and/or the sealing structure 400 of FIGS. 4A-4B.

At operation 510, a base sealing structure is obtained. The base sealing structure can be formed from any suitable material. In some embodiments, the base sealing structure is a metal base sealing structure formed from a metal. In some embodiments, the base sealing structure is a plastic base sealing structure formed from a plastic. Examples of base sealing structures include O-rings, gaskets, T-rings, square O-rings, X-rings, D-rings, V-rings, rectangular rings, U-cups, S-shaped rings, or any other suitable sealing structures.

At operation 520, an elastomer is formed on a surface of the base sealing structure to form a sealing structure. In some embodiments, forming the elastomer on the surface of the base sealing structure includes bonding the elastomer to the surface of the base sealing structure. In some embodiments, the elastomer includes a single layer of elastomer material. In some embodiments, the elastomer includes multiple layers of elastomer materials.

At operation 530, the sealing structure is placed within a flange to form a seal between a processing chamber and a region external to the processing chamber.

In some embodiments, the surface of the base sealing structure obtained at operation 510 includes a first portion to be exposed to a process chemistry and a second portion that will not be exposed to the process chemistry. In some embodiments, the elastomer includes a material resistant to the process chemistry that formed on (e.g., bonded to) the first portion at operation 520, and the second portion is not covered by the elastomer. For example, the material resistant to the process chemistry can include at least one PFAS material (e.g., at least one of: a perfluoroalkyl substance or a polyfluoroalkyl substance). Although the elastomer may be formed from a PFAS material, less PFAS material will be needed to form the sealing structure as compared to a sealing structure that is formed entirely from a PFAS material. Accordingly, these embodiments can be used to reduce the amount of PFAS materials used to form sealing structures as compared to sealing structures formed entirely from PFAS materials. In other embodiments, the first portion is not covered by an elastomer, and the elastomer formed on (e.g., bonded to) the second portion at operation 520.

In some embodiments, the base sealing structure obtained at operation 510 includes an O-ring (e.g., metal O-ring or plastic O-ring). For example, a cross-section of the base sealing structure can have a circular shape. Examples of base sealing structures with cross-sections having circular shapes include tori, toroids, etc. In some embodiments, the elastomer is formed around an entirety of the surface of the O-ring. For example, the elastomer can be formed from a material resistant to the process chemistry (e.g., at least one PFAS material).

In some embodiments, the elastomer is formed around less than entirety of the surface of the O-ring at operation 520. For example, the elastomer can be formed on (e.g., bonded to) a first portion of the surface of the O-ring that is exposed to a region external to the processing chamber (e.g., atmosphere), and a second portion of the O-ring not covered by the elastomer is exposed to an opening to a processing chamber. In these embodiments, the second portion of the O-ring can be formed to be resistant to one or more processes chemistries that can be used by the processing chamber. For example, at least the second portion of the O-ring can be coated with a material resistant to the one or more process chemistries. In these embodiments, since the elastomer formed on (e.g., bonded to) the first portion of the O-ring is not exposed to the one or more process chemistries, the elastomer can be formed from any suitable elastomer material (e.g., non-PFAS or PFAS). Accordingly, these embodiments can be used to reduce or eliminate the amount of PFAS materials used to form sealing structures as compared to sealing structures formed entirely from PFAS materials.

As another example, at operation 520, the elastomer can be formed on (e.g., bonded to) a first portion of the surface of the O-ring that is exposed to an opening to a processing chamber, and a second portion of the surface of the O-ring is exposed to a region external to the processing chamber (e.g., atmosphere). In these embodiments, since the second portion of the closed loop is not exposed to the opening of the processing chamber, the second portion of the closed loop may be left untreated. In these embodiments, the elastomer can be formed from an elastomer material that is resistant to one or more processes chemistries that can be used by the processing chamber. For example, the elastomer can be formed from a suitable PFAS material. Accordingly, these embodiments can be used to reduce the amount of PFAS materials used to form sealing structures as compared to sealing structures formed entirely from PFAS materials.

In some embodiments, a cross-section of the base sealing structure obtained at operation 510 has a non-circular shape. For example, the non-circular shape can be an open loop shape (e.g., a C-shaped loop). In these embodiments, at operation 520, the elastomer can be formed on (e.g., bonded to) to an outer surface of the open loop, such that an inner surface of the open loop is left uncovered. In some embodiments, the open loop shape includes flared ends that extend past the elastomer boundary. Such flared regions can protect the elastomer from exposure to a process chemistry by providing an extra barrier between the process chemistry and the elastomer. This can enable the use of less chemically resistant elastomers (e.g., silicone or other non-PFAS materials), and can extend the life of the O-ring as well.

In some embodiments, the elastomer formed on the outer surface of the open loop shape is exposed to a region external to a processing chamber (e.g., atmosphere), and the inner surface of the open loop is exposed to an opening of the processing chamber. In these embodiments, the inner surface of the open loop can be formed to be resistant to one or more processes chemistries that can be used by the processing chamber. For example, at least the inner surface of the open loop can be coated with a material resistant to the one or more process chemistries. In these embodiments, since the elastomer is not exposed to the opening of the processing chamber, the elastomer can be formed from any suitable elastomer material (e.g., non-PFAS or PFAS). Accordingly, these embodiments can be used to reduce or eliminate the amount of PFAS materials used to form sealing structures as compared to sealing structures formed entirely from PFAS materials.

In some embodiments, the elastomer formed on the outer surface of the open loop is exposed to an opening of a processing chamber, and the inner surface of the open loop is exposed to a region external to the processing chamber (e.g., atmosphere). In these embodiments, the elastomer is formed from an elastomer material that is resistant to one or more processes chemistries that can be used by the processing chamber. For example, the elastomer can be formed from a suitable PFAS material. In these embodiments, since the inner surface of the open loop is not exposed to the opening of the processing chamber, the inner surface of the open loop may be left untreated. Accordingly, these embodiments can be used to reduce the amount of PFAS materials used to form sealing structures as compared to sealing structures formed entirely from PFAS materials. Further details regarding blocks 510-530 are described above with reference to FIGS. 1-4B.

FIGS. 6A-6B are diagrams illustrating cross-sectional views of an example system including an elastomer sealing structure for a processing chamber, in accordance with some embodiments. For example, FIG. 6A is a diagram 600A showing an initial state of a system including a lid 610 of a processing chamber (e.g., the processing chamber 114 of FIG. 1), a body 620 of the processing chamber, and an elastomer sealing structure 630 located between the lid 610 and the body 620. In this illustrative example, the elastomer sealing structure 630 is located between the lid 610 and the body 620 to maintain a vacuum seal. More specifically, the elastomer sealing structure 630 can provide a barrier against air from the atmosphere entering the processing chamber (e.g., air flowing from the right to left).

The elastomer sealing structure 630 can be formed from a material (e.g., a polymer) that lacks PFAS (e.g., a non-PFAS material), and that can naturally break down upon exposure to a corrosive environment. The material can be a non-toxic material. One example of a material that can be used to form the elastomer sealing structure 630 is polyethylene ((C₂H₄)ₙ). In some embodiments, the elastomer sealing structure 630 is formed from HDPE. For example, the elastomer sealing structure 630 can be formed from polyethylene having a density of greater than or equal to about 900 kilograms per cubic meter (kg/m³). Other examples of materials (e.g., polymers) include polypropylene, polyimide, nylon (e.g., nylon 66), EPDM, silicone rubber, etc. In some embodiments, the elastomer sealing structure 630 is formed from XLPE or XLHDPE. Other examples of materials (e.g., polymers) include polypropylene, polyimide, nylon (e.g., nylon 66), ethylene-propylene diene monomer EPDM, silicone rubber, etc. However, any suitable polymer that can naturally break down after disposal including at least one of: C, H, O, N, Si, S, etc. can be used to form the elastomer sealing structure 630 in accordance with embodiments described herein.

The elastomer sealing structure 630 can have a suitable width so that it does not substantially interfere with other components in the wall of the processing chamber. In some embodiments, the elastomer sealing structure 630 has a width that is less than or equal to about 1 centimeter (cm). In some embodiments, the elastomer sealing structure 630 has an aspect ratio of less than or equal to about 100:1. In some embodiments, the elastomer sealing structure 630 has an aspect ratio of less than or equal to about 50:1. In some embodiments, the elastomer sealing structure 630 has an aspect ratio of less than or equal to about 10:1. In some embodiments, the elastomer sealing structure 630 has an aspect ratio of less than or equal to about 5:1. In some embodiments, the elastomer sealing structure 630 has an aspect ratio of less than or equal to about 1:1.

The compressive force exerted by the lid 610 onto the elastomer sealing structure 630 is represented by an arrow 640A, and the compressive forced exerted by the body 620 onto the elastomer sealing structure 630 is represented by an arrow 650A.

The elastomer sealing structure 630 can be a sacrificial sealing structure to be exposed to a corrosive chemical environment within the processing chamber. If the elastomer sealing structure is formed from a non-PFAS material, then the corrosive chemical environment can cause erosion of the elastomer sealing structure 630 over time. For example, FIG. 6B is a diagram 600B showing a state of the system in which the elastomer sealing structure 630 has been eroded by a corrosive chemical environment within the processing chamber resulting in a remaining portion of the elastomer sealing structure 630.

The elastomer sealing structure 630 shown in FIG. 6A can have a shape that, as the elastomer sealing structure 630 is eroded by the corrosive chemical environment, can cause the compressive force exerted by the lid 610 and the body 620 (represented by the arrows 640A and 640B in FIG. 6A) onto the elastomer sealing structure to shift toward the center of the remaining portion of the elastomer sealing structure 630 to maintain the seal. For example, the elastomer sealing structure 630 can have a ribbon shape (e.g., a wide ribbon shape), instead of a traditional O-ring shape. For example, the ribbon shape can be a flattened O-ring shape, similar to a rubber band.

Since the elastomer sealing structure 630 can be a sacrificial sealing structure formed from a non-PFAS material that erodes upon exposure to a corrosive chemical environment, the elastomer sealing structure 630 will eventually need to be replaced when the remaining portion of the elastomer sealing structure 630 satisfies a threshold condition (e.g., when the cross-sectional length of the elastomer sealing structure 630 is less than or equal to a threshold length). Moreover, based on an analysis of corrosion rate of the elastomer sealing structure 630 over time, a preventative maintenance schedule (e.g., based on maintenance cycles) can be devised to determine (e.g., predict) when to replace the elastomer sealing structure 630. For example, the elastomer sealing structure can be replaced if it determined that less than or equal to about 50% of the elastomer sealing structure is remaining. The frequency of this maintenance can be determined experimentally, can and depend on the process and/or application for which the elastomer sealing structure is being utilized. In some embodiments, an alert is generated in response to determining (e.g., predicting) when the elastomer sealing structure 630 is due to be replaced.

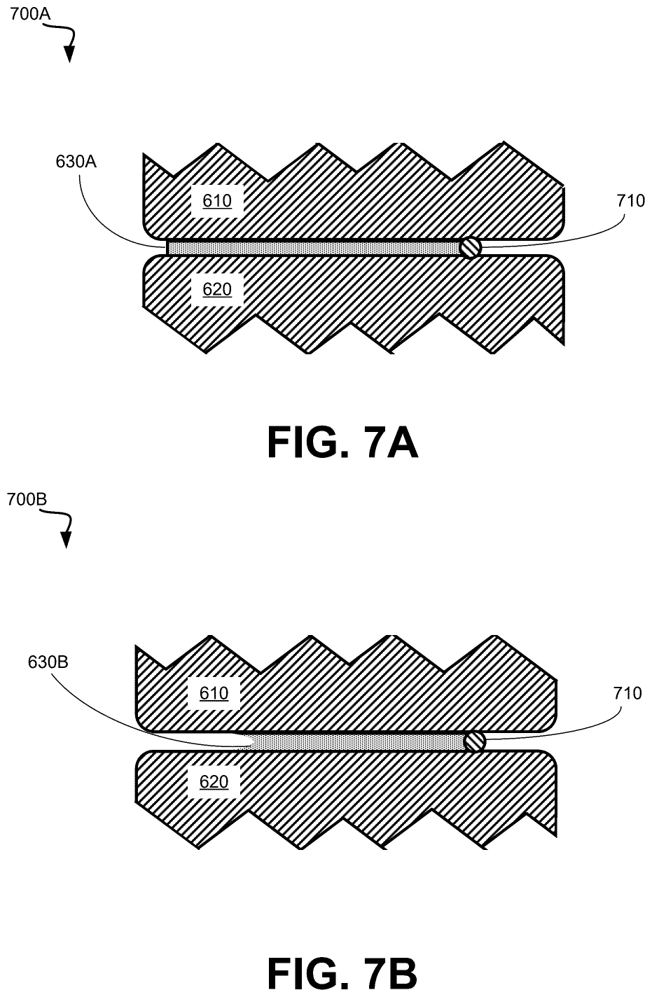

FIGS. 7A-7B are diagrams illustrating cross-sectional views of an example system including an elastomer sealing structure and a metal sealing structure for a processing chamber, in accordance with some embodiments. For example, FIG. 7A is a diagram 700A showing an initial state of a system including the lid 610, the body 620 and the elastomer sealing structure 630, as described above with reference to FIG. 6A.

In this illustrative example, a metal sealing structure 710 is located between the lid 610 and the body 620 to form a vacuum seal. For example, the metal sealing structure 710 can be a metal O-ring, a metal gasket, etc. The metal sealing structure 710 can provide a barrier against air from the atmosphere entering the processing chamber (e.g., air flowing from the right to left). In these embodiments, the elastomer sealing structure 630 is configured to protect the metal sealing structure from the corrosive chemical environment within the processing chamber. Accordingly, in these embodiments, the metal sealing structure 710 is primarily responsible for forming the vacuum seal, and the elastomer sealing structure 630 primarily functions as a barrier for the metal sealing structure 710 against the corrosive chemical environment. For example, FIG. 7B is a diagram 700B showing a state of the system in which the elastomer sealing structure 630 has eroded by the corrosive chemical environment within the processing chamber, as described above with reference to FIG. 6B.

Since the elastomer sealing structure 630 is formed from a non-PFAS material that erodes upon exposure to a corrosive chemical environment, the elastomer sealing structure 630 will eventually need to be replaced when the remaining portion of the elastomer sealing structure 630 satisfies a threshold condition (e.g., when the cross-sectional length of the elastomer sealing structure 630 is less than or equal to a threshold length). Moreover, based on an analysis of corrosion rate of the elastomer sealing structure 630 over time, a preventative maintenance schedule (e.g., based on maintenance cycles) can be devised to determine (e.g., predict) when to replace the elastomer sealing structure 630. For example, the elastomer sealing structure can be replaced if it determined that less than or equal to about 50% of the elastomer sealing structure is remaining. The frequency of this maintenance can be determined experimentally, can and depend on the process and/or application for which the elastomer sealing structure is being utilized. In some embodiments, an alert is generated in response to determining (e.g., predicting) when the elastomer sealing structure 630 is due to be replaced.

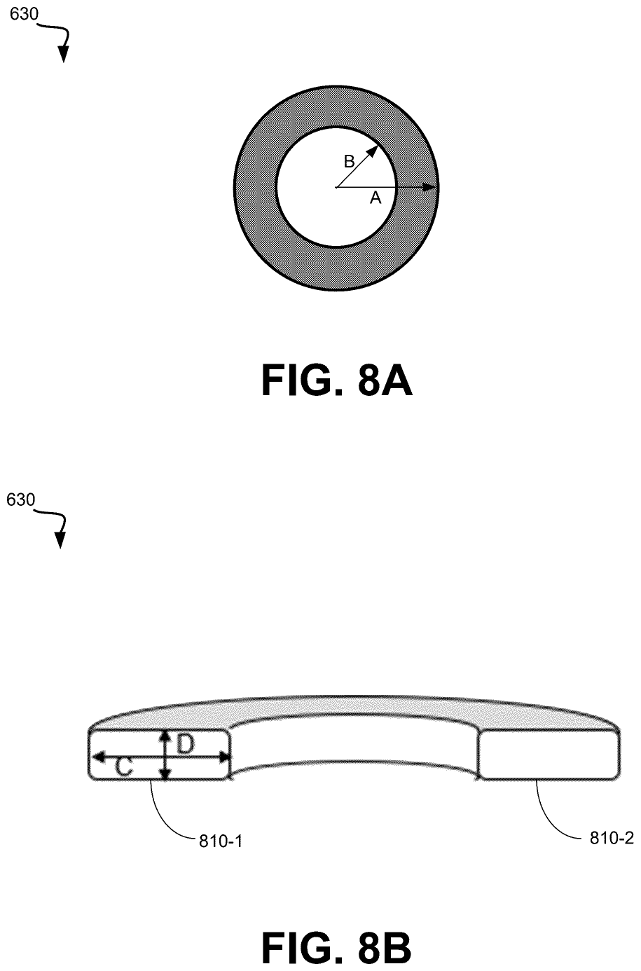

The threshold condition in the embodiments shown in FIGS. 7A-7B can be different from the threshold condition in the embodiments shown in FIGS. 6A-7B, at least because the metal sealing structure 710 is what is primarily responsible for forming the vacuum seal. For example, the threshold length for the elastomer sealing structure 630 shown in FIGS. 7A-7B can less than the threshold length for the elastomer sealing structure 630 shown in FIGS. 6A-6B. Further details regarding the elastomer sealing structure 630 will now be described below with reference to FIGS. 8A-8B.

FIG. 8A is a diagram of a top-down view of an example elastomer sealing structure 630, in accordance with some embodiments. As shown, the elastomer sealing structure 630 can have an annulus shape with respect to the top-down view. In the embodiment shown in FIG. 8A, the elastomer sealing structure 630 has a circular annulus shape or approximately circular annulus shape with respect to the top-down view. In other embodiments, the elastomer sealing structure 630 has a non-circular annulus shape with respect to the top-down view (e.g., elliptical annulus shape).

For example, the elastomer sealing structure 630 can have a center-to-outer edge distance “A” and a center-to-inner edge distance “B”. In the case of a circular annulus shape, the distance “A” can be an outer radius (i.e., the radius of the larger circle) and the distance “B” can be an inner radius (i.e., the radius of the smaller circle). In some embodiments, the distance “A” ranges between about 2 millimeters (mm) to about 1000 mm. In some embodiments, the distance “B” ranges between about 1 mm to about 980 mm.

FIG. 8B is a diagram of a perspective cutaway view of an example elastomer sealing structure 630, in accordance with some embodiments. As shown, when cut open, the elastomer sealing structure 630 can have a pair of ends 810-1 and 810-2. Each of the ends 810-1 and 810-2 can have a ribbon-shaped (e.g., rounded rectangular shaped) cross-section or approximately ribbon-shaped cross-section. For example, as shown with respect to the end 810-1, the cross-section can be defined by a distance “C” and a distance “D”. In some embodiments, the distance “C” ranges between about 2 mm to about 1000 mm. In some embodiments, the distance “D” ranges between about 1 mm to about 980 mm.

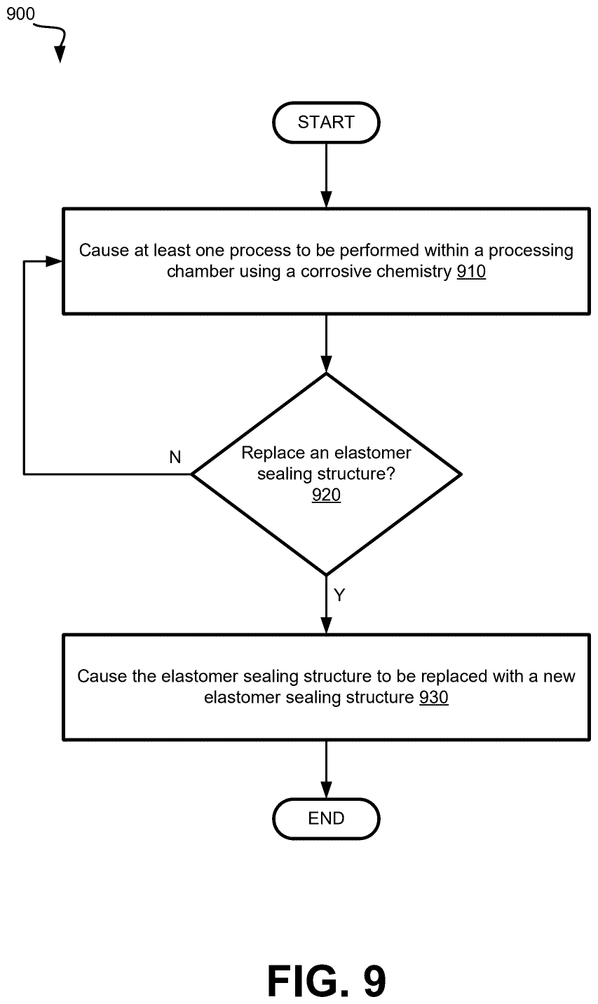

FIG. 9 is a flowchart of an example method 900 to implement an elastomer sealing structure for a processing chamber, in accordance with some embodiments. For example, the method 900 can be performed by a system controller, such as the system controller 128 of FIG. 1. For example, the elastomer sealing structure may be similar to the elastomer sealing structure 630 of FIGS. 6A-8B.

At operation 910, processing logic causes at least one process to be performed within a processing chamber using a corrosive chemistry. The processing chamber can include a lid and a body.

At operation 920, processing logic determines whether to replace an elastomer sealing structure. More specifically, the elastomer sealing structure can be placed between the lid of the processing chamber and the body of the processing chamber. The elastomer sealing structure can have a ribbon shape and include a material that lacks PFAS. One example of a material that can be used to form the elastomer sealing structure is polyethylene ((C₂H₄)ₙ). In some embodiments, the elastomer sealing structure is formed from HDPE. For example, the elastomer sealing structure can be formed from polyethylene having a density of greater than or equal to about 900 kg/m³. In some embodiments, the elastomer sealing structure is formed from XLPE or XLHDPE. Other examples of materials (e.g., polymers) include polypropylene, polyimide, nylon (e.g., nylon 66), ethylene-propylene diene monomer (EPDM), silicone rubber, etc. However, any suitable polymer that can naturally break down after disposal including at least one of: C, H, O, N, Si, S, etc. can be used to form the elastomer sealing structure in accordance with embodiments described herein.

In some embodiments, the elastomer sealing structure forms a vacuum seal. In some embodiments, the elastomer sealing structure is adjacent to a metal sealing structure located between the lid and the body. In these embodiments, the metal sealing structure is primarily responsible for forming the vacuum seal, and the elastomer sealing structure is configured to protect the metal sealing structure from the corrosive chemical environment within the processing chamber.

Since the elastomer sealing structure is formed from a non-PFAS material, the corrosive chemical environment within the processing chamber caused by the corrosive chemistry can erode the elastomer sealing structure over time. Thus, at operation 930, processing logic determines whether to replace the elastomer sealing structure. In some embodiments, determining whether to replace the elastomer sealing structure includes determining whether a remaining portion of the elastomer sealing structure satisfies a threshold condition (e.g., when the cross-sectional length of the elastomer sealing structure is less than or equal to a threshold length). Determining whether to replace the elastomer sealing structure can include analyzing corrosion rate of the elastomer sealing structure over time to determine (e.g., predict) when to replace the elastomer sealing structure.

At operation 930, processing logic causes the elastomer sealing structure to be replaced with a new elastomer sealing structure. The new elastomer sealing structure can be similar to the elastomer sealing structure being replaced (e.g., have a ribbon shape and be formed from a material that lacks PFAS). In some embodiments, causing the elastomer sealing structure to be replaced with a new elastomer sealing structure includes generating an alert to replace the elastomer sealing structure with a new elastomer sealing structure.

It should be borne in mind, however, that all of these and similar terms are to be associated with the appropriate physical quantities and are merely convenient labels applied to these quantities.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within +10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A system comprising:
a base sealing structure comprising an O-ring, wherein a cross-section of the base sealing structure has a circular shape; and
an elastomer bonded to a surface of the base sealing structure to form a sealing a structure, wherein the elastomer is formed around at least a portion of the surface of the O-ring.

2. The system of claim 1, wherein the surface of the base sealing structure comprises a first portion to be exposed to a process chemistry and a second portion that will not be exposed to the process chemistry, wherein the elastomer comprises a material resistant to the process chemistry that is bonded to the first portion, and wherein the second portion is not covered by the elastomer.

3. The system of claim 1, wherein the surface of the base sealing structure comprises a first portion to be exposed to a process chemistry and a second portion that will not be exposed to the process chemistry, wherein the first portion is not covered by the elastomer, and wherein the elastomer is bonded to the second portion.

4. The system of claim 1, wherein the elastomer is formed around an entirety of the surface of the O-ring.

5. The system of claim 1, wherein the elastomer is formed around less than an entirety of the surface of the O-ring.

6. The system of claim 1, wherein a cross-section of the base sealing structure has an open loop shape having flared ends.

7. The system of claim 1, wherein a cross-section of the base sealing structure has an open loop shape comprising an inner surface configured to be resistant to a process chemistry.

8. The system of claim 1, wherein a cross-section of the base sealing structure has an open loop shape comprising an outer surface configured to be resistant to a process chemistry.

9. The system of claim 1, wherein the base sealing structure is a metal base sealing structure.

10. The system of claim 1, wherein the base sealing structure is a plastic base sealing structure.

11. The system of claim 1, further comprising:
a processing chamber; and
a flange connected to the processing chamber, wherein the sealing structure is placed within the flange to form a seal between the processing chamber and a region external to the processing chamber.

12. A system comprising:
a lid of a processing chamber;
a body of processing chamber; and
an elastomer sealing structure located between the lid and the body, wherein the elastomer sealing structure has a ribbon shape and comprises a material that lacks per- and/or polyfluoroalkyl substances (PFAS).

13. The system of claim 12, wherein the elastomer sealing structure comprises at least one of: polyethylene, polypropylene, polyimide, nylon (e.g., nylon 66), ethylene-propylene diene monomer, or silicon rubber.

14. The system of claim 12, wherein the elastomer sealing structure comprises high-density polyethylene (HDPE).

15. The system of claim 12, wherein the elastomer sealing structure comprises cross-linked polyethylene (XLPE) or high-density crosslinked polyethylene (XLHDPE).

16. The system of claim 12, wherein the elastomer sealing structure has a flattened O-ring shape having a ribbon-shaped cross-section or an approximately ribbon-shaped cross-section.

17. The system of claim 12, further comprising a metal sealing structure located between the lid and the body and adjacent to the elastomer sealing structure, wherein the elastomer sealing structure is configured to protect the metal sealing structure from a corrosive chemical environment within the processing chamber.

18. A method comprising:
causing, within a processing chamber comprising a lid and a body, at least one process to be performed using a corrosive chemistry, wherein an elastomer sealing structure is located between the lid and the body, and wherein the elastomer sealing structure has a ribbon shape and comprises a material that lacks per- and/or polyfluoroalkyl substances (PFAS);
determining whether to replace the elastomer sealing structure; and
in response to determining to replace the elastomer sealing structure, causing the elastomer sealing structure to be replaced with a new elastomer sealing structure having a ribbon shape and comprising a material that lacks PFAS.

19. The method of claim 18, wherein the elastomer sealing structure is adjacent to a metal sealing structure located between the lid and the body, and wherein the elastomer sealing structure is configured to protect the metal sealing structure from a corrosive chemical environment within the processing chamber.

20. The method of claim 18, wherein determining whether to replace the elastomer sealing structure comprises determining whether less than or equal to 50% of the elastomer sealing structure is remaining.
